(19) United States
(12) Patent Application Publication
(10) Pub. No.: US 2026/0333919 A1
(43) Pub. Date: Oct. 22, 2026

(54) IMAGE SENSOR

(71) Applicant: Samsung Electronics Co., Ltd., Suwon-si (KR)

(72) Inventors: KWANYOUNG OH, Suwon-si (KR); SEONOK KIM, Suwon-si (KR); HAEWON LEE, Suwon-si (KR)

(21) Appl. No.: 19/649,256

(22) Filed: Apr. 16, 2026

(30) Foreign Application Priority Data
Apr. 21, 2025 (KR) 10-2025-0051851

(51) Int. Cl. H10F 39/00

(52) U.S. Cl. CPC H10F 39/807; H10F 39/8037

(57) ABSTRACT

An image sensor includes a floating diffusion region in a substrate, a first transistor connected to the floating diffusion region and a second transistor connected to the first transistor, and a capacitor connected between the first transistor and the second transistor. The capacitor includes a first electrode and a second electrode that overlap with an insulating layer interposed therebetween. The substrate has a trench, and at least a portion of the first electrode is located in the trench and at least a first portion of the second electrode is located on the substrate.

### CROSS-REFERENCE TO RELATED APPLICATION

This application is based on and claims priority to Korean Patent Application No. 10-2025-0051851 filed on Apr. 21, 2025, in the Korean Intellectual Property Office, the disclosure of which is incorporated by reference herein in its entirety.

### BACKGROUND

### 1. Field

The present disclosure relates to an image sensor.

### 2. Description of the Related Art

An image sensor is a semiconductor device that converts an optical image into an electrical signal. Image sensors may be classified into CCD (Charge coupled device) and CMOS (Complementary metal oxide semiconductor).

A CMOS image sensor (CIS), compared to a CCD image sensor which has a high-voltage analog circuit, has advantages of a low manufacturing cost and a small device size, leading to low power consumption, and thus CIS is mainly mounted in home appliances including portable devices such as smartphones and digital cameras.

The pixel array constituting the CIS includes a photoelectric conversion component such as a photodiode for each pixel. The photodiode generates an electrical signal that varies according to the amount of incident light, and the CMOS image sensor may process the electrical signal to synthesize an image.

The operating characteristics of the image sensor in dark environments and bright environments may be different.

In response to recent demands for high-resolution images, the pixel size of the image sensor is decreasing and the number of pixels is increasing. Accordingly, the area of the region where the elements included in the image sensor may be placed is decreasing.

### SUMMARY

Embodiments are intended to provide an image sensor capable of maintaining the operating characteristics of a high-resolution image sensor according to changes in the environment.

However, the problems that the embodiments seek to solve are not limited to the problems described above and may be variously expanded within the scope of the technical ideas included in the embodiments.

In embodiments, an image sensor includes a floating diffusion region in a substrate, a first transistor connected to the floating diffusion region and a second transistor connected to the first transistor, and a capacitor connected between the first transistor and the second transistor. The capacitor includes a first electrode and a second electrode that overlap with an insulating layer interposed therebetween. The substrate has a trench, and at least a portion of the first electrode is located in the trench and at least a first portion of the second electrode is located on the substrate.

In embodiments, an image sensor includes a floating diffusion region in a substrate, a first transistor connected to the floating diffusion region and a second transistor connected to the first transistor, and a first capacitor and a second capacitor connected in parallel between the first transistor and the second transistor.

According to embodiments, it is possible to provide an image sensor capable of maintaining the operating characteristics of a high-resolution image sensor according to environmental changes may be provided.

However, the effects of the embodiments are not limited to the effects described above, and it is apparent that they can be variously expanded without departing from the spirit and scope of the embodiments.

### BRIEF DESCRIPTION OF THE DRAWINGS

FIG. 1 is a block diagram schematically illustrating an image sensor according to one or more embodiments.

FIG. 2 is a plan view illustrating a portion of an image sensor according to one or more embodiments.

FIG. 3 is an equivalent circuit diagram of an image sensor according to one or more embodiments.

FIG. 4 is a plan view of a portion of an image sensor according to one or more embodiments.

FIG. 5 is a cross-sectional view taken along line I-I′ of FIG. 4.

FIG. 6 is a cross-sectional view taken along line II-II′ of FIG. 4.

FIG. 7 is a cross-sectional view taken along line III-III′ of FIG. 4.

FIGS. 8 to 13 are cross-sectional views illustrating a method for manufacturing an image sensor according to one or more embodiments.

FIG. 14 is an equivalent circuit diagram of an image sensor according to one or more embodiments.

FIG. 15 is a plan view of an image sensor according to one or more embodiments.

FIG. 16 is an equivalent circuit diagram of an image sensor according to one or more embodiments.

FIG. 17 is a plan view of an image sensor according to one or more embodiments.

FIG. 18 is an equivalent circuit diagram of an image sensor according to one or more embodiments.

FIG. 19 is a plan view of an image sensor according to one or more embodiments.

### DETAILED DESCRIPTION

In the following detailed description, only certain embodiments have been shown and described, simply by way of illustration. This disclosure can be variously implemented and is not limited to the following embodiments.

The drawings and description are to be regarded as illustrative in nature and not restrictive. Like reference numerals designate like elements throughout the specification.

Further, the accompanying drawings are provided to help understand embodiments disclosed in the present specification, and the technical spirit disclosed in the present specification is not limited by the accompanying drawings, and it will be appreciated that this disclosure includes all of the modifications, equivalent matters, and substitutes included in the spirit and the technical scope of this disclosure.

In addition, the size and thickness of each configuration shown in the drawings are arbitrarily shown for understanding and ease of description, but this disclosure is not limited thereto. In the drawings, the thickness of layers, films, panels, regions, etc., are exaggerated for clarity. Further, in the drawings, for understanding and ease of description, the thickness of some layers and areas is exaggerated.

Further, it will be understood that when an element, such as a layer, film, region, or substrate is referred to as being “on” another element, it can be directly on the other element or intervening elements may also be present. In contrast, when an element is referred to as being “directly on” another element, or as contacting another element, there are no intervening elements present at the point of contact. Further, when an element is “on” a reference portion, the element is located above or below the reference portion, and it does not necessarily mean that the element is located “above” or “on” in a direction opposite to gravity.

In addition, in the entire specification, unless explicitly described to the contrary, the word “comprise,” and variations such as “comprises” or “comprising,” will be understood to imply the inclusion of stated elements but not the exclusion of any other elements.

Further, throughout the specification, when it is referred to as “connected,” this does not only mean that two or more constituent elements are directly connected, but may mean that two or more constituent elements are indirectly connected through another constituent element, are physically connected, electrically connected, or are integrated even though two or more constituent elements are referred as different names depending on a location and a function.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

As used herein, components described as being “electrically connected” are configured such that an electrical signal can be transferred from one component to the other (although such electrical signal may be attenuated in strength as it is transferred and may be selectively transferred).

Spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

Hereinafter, various embodiments and modifications will be described in detail with reference to the drawings.

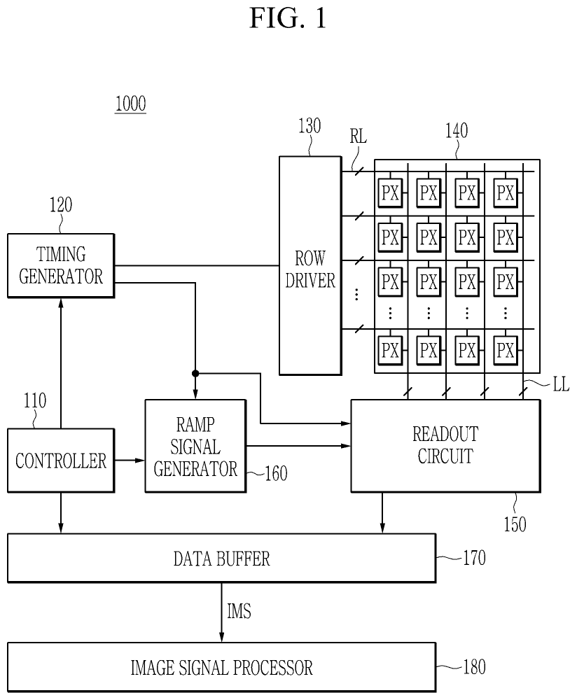

Referring to FIG. 1, an image sensor according to one or more embodiments will be schematically described. FIG. 1 is a block diagram schematically illustrating an image sensor according to one or more embodiments.

Referring to FIG. 1, an image sensor 1000 according to one or more embodiments may include a pixel array 140 and a logic circuit that controls the pixel array 140.

The logic circuit is a circuit for controlling the pixel array 140 and may include, for example, a controller 110, a timing generator 120, a row driver 130, a readout circuit 150, a ramp signal generator 160, a data buffer 170, etc.

The image sensor 1000 may further include an image signal processor 180, and according to another embodiment, the image signal processor 180 may be located external to the image sensor 1000. The image sensor 1000 may generate an image signal by converting light received from the outside into an electrical signal. The image signal may be provided to an image signal processor 180.

The image sensor 1000 may be mounted on an electronic device having an image sensing function or a light sensing function. For example, the image sensor 1000 may be mounted in electronic apparatuses such as cameras, smart phones, wearable devices, Internet of Things (IoT) devices, home appliances, tablet personal computers (PCs), navigation devices, drones, advanced driver assistance systems (ADASs), etc. Also, the image sensor 100 may be mounted in electronic apparatuses which are incorporated as components in vehicles, furniture, manufacturing equipment, doors, various measuring devices, etc.

The pixel array 140 may include a plurality of pixels PX, and a plurality of row lines RL and a plurality of column lines CL connected to the plurality of pixels PX.

In one or more embodiments, each pixel PX may include at least one photodiode. The photodiode may detect incident light, and convert the incident light into an electrical signal according to the amounts of light, e.g., into a pixel signal.

The photodiode may be a pinned diode, etc. The photodiode may be a single-photon avalanche diode (SPAD) that is applied to a three-dimensional (3D) sensor pixel.

The level of an analog pixel signal which is output from the photodiode may be proportional to the amount of charge which is output from the photodiode. Therefore, the level of the analog pixel signal which is output from the photodiode may be determined depending on the amount of light which enters the pixel array 140

The plurality of row lines RL may be connected to the plurality of pixels PX. For example, a control signal that is output from the row driver 130 to a row line RL may be transferred to the gates of the transistors of a plurality of pixels PX connected to the corresponding row line RL. Each column line CL may be disposed so as to intersect the row lines RL and may be connected to a plurality of pixels PX. A plurality of pixel signals output from the plurality of pixels PX may be transferred to the readout circuit 150 through the plurality of column lines CL.

The controller 110 may control the operation timing of the above-mentioned individual constituent elements 120, 130, 150, 160, and 170, using control signals.

In one or more embodiments, the controller 110 may receive a mode signal indicating an imaging mode from an application processor, and generally control the image sensor 1000 based on the received mode signal. For example, the application processor may determine the imaging mode of the image sensor 1000 according to various scenarios such as the intensity of illumination in the imaging environment, the user's resolution setting, a sensed or learned state, etc., and provide the determined result to the controller 110 as the mode signal.

The controller 110 may control the plurality of pixels PX of the pixel array 140, such that the pixels output pixel signals depending on the imaging mode, and the pixel array 140 may output the pixel signals of the plurality of pixels PX or the pixel signals of some of the plurality of pixels PX, and the readout circuit 150 may sample and process the pixel signals received from the pixel array 140.

The timing generator 120 may generate a signal to be a reference for the operation timing of the components of the image sensor 100. The timing generator 120 may control the timing of the row driver 130, the readout circuit 150, and the ramp signal generator 160. The timing generator 120 may provide control signals to control the timing of the row driver 130, the readout circuit 150, and the ramp signal generator 160.

The row driver 130 may generate a control signal for driving the pixel array 140, in response to receiving the control signals of the timing generator 120, and provide the control signal to the plurality of pixels PX of the pixel array 140 through the plurality of row lines RL.

In one or more embodiments, the row driver 130 may control the pixels PX in units of a row line, such that the pixels detect incident light. Each row line unit may include at least one row line RL. For example, the row driver 130 may generate a transfer signal for controlling transfer transistors, a reset control signal for controlling reset transistors, a selection control signal for controlling selected transistors, etc., and provide the signals to the pixel array 140.

The readout circuit 150 may convert the pixel signals (or electrical signals) received from pixels PX coupled to a selected row line RL among the plurality of pixels PX, into pixel values indicating light amounts, in response to the control signal from the timing generator 120.

The readout circuit 150 may convert pixel signals output through corresponding column lines CL into pixel values. For example, the readout circuit 150 may convert pixel signals into pixel values by comparing the pixel signals with ramp signals. Pixel values may be image data items, each of which has a plurality of bits. The readout circuit 150 may include a selector, a plurality of comparators, a plurality of counter circuits, etc.

The ramp signal generator 160 may generate a reference signal, and transmit the reference signal to the readout circuit 150. The ramp signal generator 160 may include current sources, resistors, and capacitors. The ramp signal generator 160 may adjust ramp voltage, which is voltage to be applied to a ramp resistor, by adjusting the current magnitudes of variable current sources or the resistance values of variable resistors. In this way, the ramp signal generator 160 may generate a plurality of ramp signals which fall or rise at slopes determined depending on the current magnitudes of variable current sources or the resistance values of variable resistors.

The data buffer 170 may store the pixel values of a plurality of pixels PX coupled to the selected column line CL, received from the readout circuit 150, and output the stored pixel values in response to an enable signal from the controller 110.

The image signal processor 180 may perform image signal processing on image signals received from the data buffer 170. For example, the image signal processor 180 may receive a plurality of image signals from the data buffer 170, and synthesize the received image signals to generate one image.

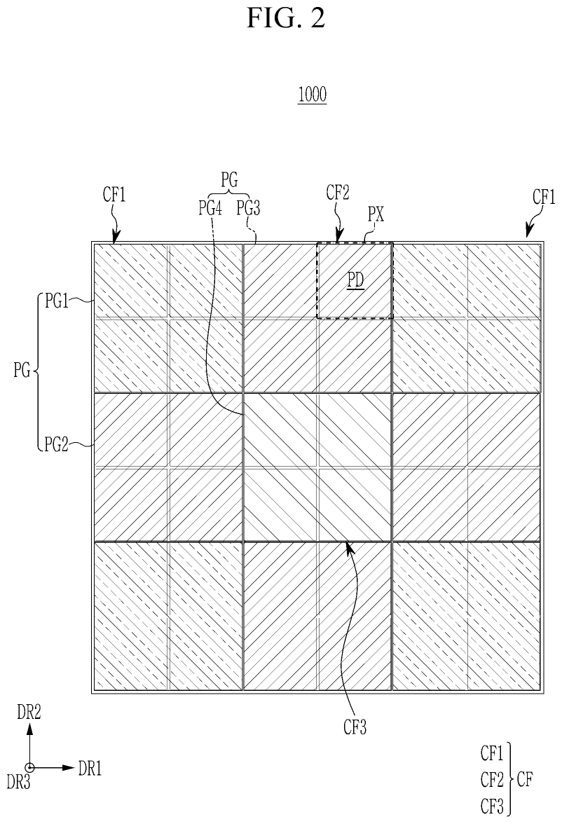

The pixel arrangement of the image sensor according to one or more embodiments will be described with reference to FIG. 2. FIG. 2 is a plan view illustrating a portion of an image sensor according to one or more embodiments.

Referring to FIG. 2, the image sensor 1000 according to one or more embodiments may include pixel groups PG1, PG2, PG3, and PG4, photodiodes PD, color filters CF, and other circuits that facilitate the operation of the image sensor 1000.

Each of the plurality of pixels PX may include one photodiode PD.

A plurality of pixels PX arranged adjacent to one another in the form of a plurality of columns and a plurality of rows may constitute pixel groups PG1, PG2, PG3, and PG4.

A pixel group PG1 overlapping a first color filter CF1 absorbs and senses light of a first color, a pixel group PG2 and a pixel group PG3 overlapping second color filters CF2 absorb and sense light of a second color different from the first color, and a pixel group PG4 overlapping a third color filter CF3 may absorb and sense light of a third color different from the first color and the second color.

In one and more embodiments, the image sensor 1000 may further include a pixel group that absorbs and senses all visible light.

According to one or more embodiments, each of the pixel groups PG1, PG2, PG3, and PG4 may include N×M pixels PX in an N×M array. N and M may each independently be an integer greater than or equal to 1. For example, N and M may each be 2 and have a pixel array of a 2×2 Tetra structure when viewed from above (e.g., in the third direction DR3). For example, each of the pixel groups PG1, PG2, PG3, and PG4 may include pixels PX arranged in a 2×2 form on a plane in a plan view.

A plurality of pixels PX arranged along a first direction DR1 and a plurality of pixels PX arranged along a second direction DR2 may constitute each of pixel groups PG1, PG2, PG3, and PG4. However, the embodiment is not limited thereto, and the number of pixels PX included in each of the pixel groups PG1, PG2, PG3, and PG4 may be variously modified.

According to one or more embodiments, the image sensor 1000 may include a first pixel row in which the pixel group PG1 corresponding to the first color filter CF1 and the pixel group PG2 corresponding to the second color filter CF2 are alternately arranged along the first direction DR1, and a second pixel row in which the pixel group PG3 corresponding to the second color filter CF2 and the pixel group PG4 corresponding to the third color filter CF3 are alternately arranged along the first direction DR1, and the first pixel row and the second pixel row may be alternately arranged along the second direction DR2.

According to one or more embodiments, the image sensor 1000 may include pixel group regions PG. Each of the pixel group regions PG may include two pixel groups among the pixel groups PG1, PG2, PG3, and PG4. The two pixel groups included in each pixel group region PG may be adjacent to each other along the second direction DR2, but the embodiment is not limited thereto, and the two pixel groups included in each pixel group region PG may also be adjacent to each other along the first direction DR1. According to one or more embodiments, each of the pixel group regions PG may include two or more pixel groups PG1, PG2, PG3, and PG4, and the number of pixel groups PG1, PG2, PG3, and PG4 included in each pixel group region PG may be changed.

The image sensor 1000 according to the embodiment may further include micro lenses, and at least one micro lens may be positioned in each of the pixel groups PG1, PG2, PG3, and PG4.

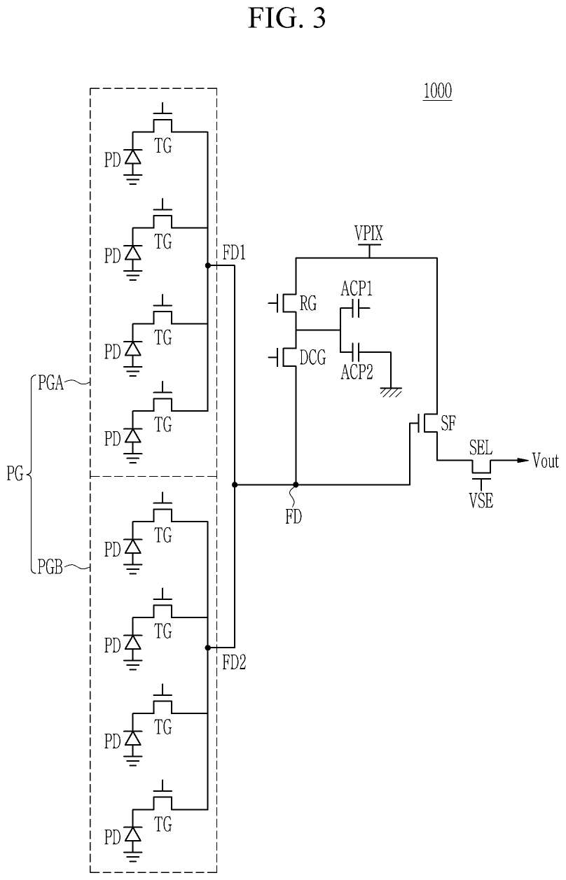

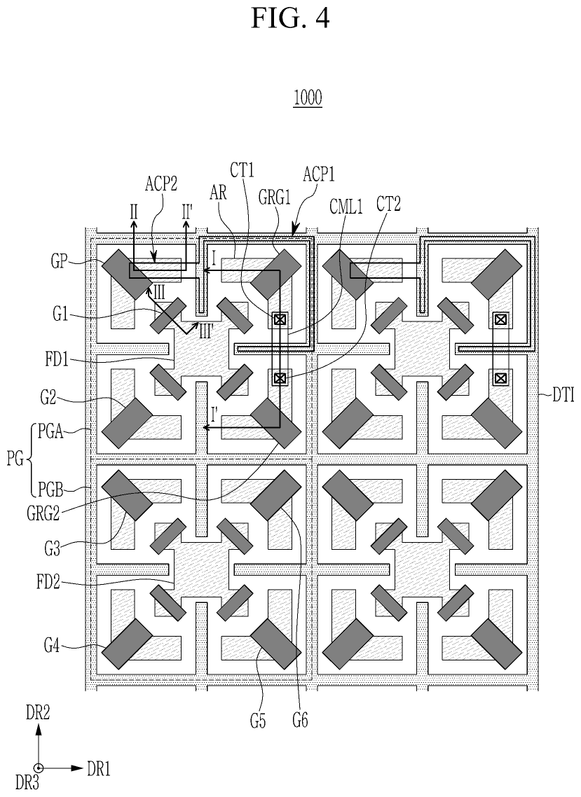

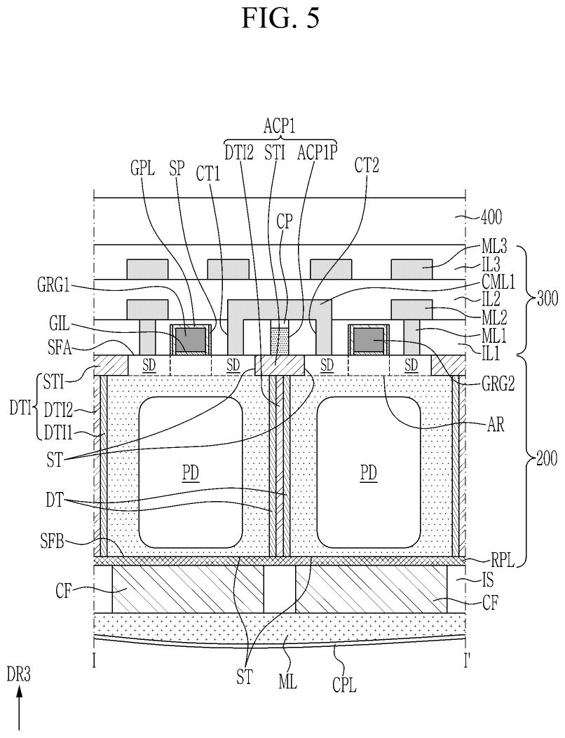

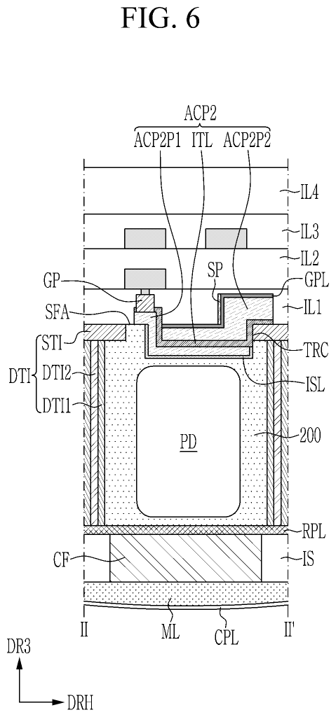

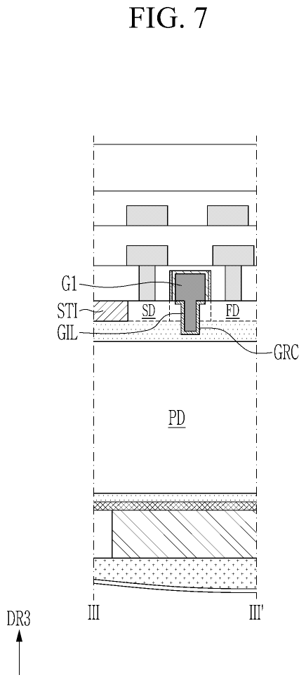

Referring to FIGS. 3 to 7 along with FIG. 2, the image sensor 1000 according to one or more embodiments will be described. FIG. 3 is an equivalent circuit diagram of an image sensor according to one or more embodiments, FIG. 4 is a plan view of a portion of an image sensor according to one or more embodiments, FIG. 5 is a cross-sectional view taken along line I-I′ of FIG. 4, FIG. 6 is a cross-sectional view taken along line II-II′ of FIG. 4, and FIG. 7 is a cross-sectional view taken along line III-III′ of FIG. 4.

Referring to FIG. 3 together with FIG. 2, one pixel group region PG of the image sensor 1000 according to one or more embodiments may include a first pixel group PGA and a second pixel group PGB.

The first pixel group PGA and the second pixel group PGB of one pixel group region PG may include a plurality of photodiodes PD, transfer transistors TG, a reset transistor RG, a dual conversion transistor DCG, a source follower transistor SF, and a selection transistor SEL.

The first pixel group PGA and the second pixel group PGB of one pixel group region PG may share the reset transistor RG, the dual conversion transistor DCG, the source follower transistor SF, and the select transistor SEL.

The first pixel group PGA and the second pixel group PGB may include a first capacitor ACP1 and a second capacitor ACP2 connected between the reset transistor RG and the dual conversion transistor DCG. The first capacitor ACP1 and the second capacitor ACP2 may be connected in parallel. By being connected between the reset transistor RG and the dual conversion transistor DCG, the first capacitor ACP1 and the second capacitor ACP2 may be connected to a node or junction that is between the reset transistor RG and the dual conversion transistor DCG, such that the first capacitor ACP1 and the second capacitor ACP2 may be electrically connected to the reset transistor RG and the dual conversion transistor DCG.

The first pixel group PGA and the second pixel group PGB may each include four photodiodes PD, but the present embodiment is not limited thereto. The number of photodiodes included in the first pixel group PGA and the second pixel group PGB may be varied.

A plurality of pixels included in the first pixel group PGA may share a first floating diffusion region FD1, for example, with the first floating diffusion region FD1 connected to the transfer transistors TG of the first pixel group PGA. A plurality of pixels in the second pixel group PGB may share a second floating diffusion region FD2, for example, with the second floating diffusion region FD2 connected to the transfer transistors TG of the second pixel group PGB.

The first floating diffusion region FD1 and the second floating diffusion region FD2 may be connected to each other to form a floating diffusion region FD.

While the transfer transistors TG are turned on by the transfer signals, the floating diffusion region FD may receive and accumulate charges from the photodiodes PD.

The reset transistor RG may provide a power voltage to the floating diffusion region FD, and the voltage of the floating diffusion region FD may be reset. When the reset transistor RG is turned on, the floating diffusion region FD and a power supply voltage Vpix may be electrically connected, and electrons stored in the floating diffusion region FD may be removed or released.

The source follower transistor SF may be connected between the power supply voltage Vpix and the select transistor SEL. The source follower transistor SF may output an output signal Vout to the select transistor SEL based on the voltage level of a floating diffusion region FD.

When the selection transistor SEL is turned on, the output signal Vout may be output to the readout circuit 150 through the column line CL.

Charges provided from photodiodes PD may be accumulated in the first capacitor ACP1 and the second capacitor ACP2 connected between the reset transistor RG and the dual conversion transistor DCG as necessary.

When the dual conversion transistor DCG is turned on while the transfer transistor TG is turned on, charges provided from the photodiodes PD may be accumulated in the floating diffusion region FD and simultaneously in the first capacitor ACP1 and the second capacitor ACP2. Through this, the FWC (Full Well Capacity) of the image sensor can be increased and the conversion gain can be decreased. The FWC is the maximum amount of electronic charge that the pixels in the image sensor 1000 are able to store before becoming saturated. In a bright state with a greater amount of ambient light, the generated charges can be sufficiently accumulated, such that benefits may be achieved by increasing the FWC due to an increase in the maximum amount of electronic charge that may be stored.

While the transfer transistor TG is in an on state, the dual conversion transistor DCG may maintain an off state, and the charges provided from the photodiodes PD may be accumulated only in the floating diffusion region FD. Through this, the amount of charge accumulation may not increase, but the conversion gain can be increased. In a dark state with little ambient light, noise can be reduced.

According to one or more embodiments, by including the first capacitor ACP1 and the second capacitor ACP2 connected between the reset transistor RG and the dual conversion transistor DCG, the amount of charge accumulation may be adjusted, so that an LCG (Low Conversion Gain) mode can be used in the bright state and an HCG (High Conversion Gain) mode can be used in the dark state, thus enabling dynamic range extension. For example, by turning on or off the dual conversion transistor DCG (e.g., by controlling the dual conversion transistor DCG), charges from the photodiodes PD may be selectively accumulated in the first capacitor ACP1 and the second capacitor ACP2, thus facilitating the amount of charge that may be accumulated by the image sensor 1000.

With reference to FIGS. 4 to 7 along with FIGS. 2 and 3, the structure of the first pixel group PGA and the second pixel group PGB of the image sensor 1000 according to one or more embodiments will be described in more detail.

As described above, an image sensor 1000 according to one or more embodiments may include the pixel group region PG including the first pixel group PGA and the second pixel group PGB that absorb and detect different colors.

Each of the first pixel group PGA and the second pixel group PGB may include the plurality of photodiodes PD. A photodiode isolation pattern DTI may be between the plurality of photodiodes PD. The photodiode isolation pattern DTI may surround at least a portion of an edge of the first pixel group PGA and the second pixel group PGB, and may be in at least some regions between the plurality of photodiodes PD within the first pixel group PGA and in at least some regions between the plurality of photodiodes PD within the second pixel group PGB. The photodiode isolation pattern DTI may prevent crosstalk between the plurality of photodiodes PD.

As illustrated in FIGS. 5-6, the image sensor 1000 may include a substrate 200. The substrate 200 may be formed of silicon (Si), germanium (Ge), or silicon-germanium (Si Ge). The substrate 200 may include gallium arsenide (GaAs), indium phosphide (InP), gallium phosphide (GaP), indium arsenide (InAs), indium antimonide (InSb), or indium gallium arsenide (InGaAs). The substrate 200 may be formed of zinc telluride (ZnTe) or cadmium sulfide (CdS).

The substrate 200 may be bulk silicon or SOI (Silicon-On-Insulator). The substrate 200 may be a silicon substrate, or may include other materials, such as silicon germanium, indium antimonide, lead tellurium compound, indium arsenide, indium phosphide, gallium arsenide, or gallium antimonide. Alternatively, the substrate 200 may be one on which an epi-layer is formed on a base substrate.

The substrate 200 may be doped with impurities of the first conductivity type. For example, the first conductivity type may be P type.

The substrate 200 may include a first surface SFA and a second surface SFB opposite to each other.

A shallow trench isolation pattern STI may be within a shallow trench ST formed in a portion of the substrate 200 from the first surface SFA of the substrate 200. The shallow trench ST may not penetrate through an entirety of the substrate 200 from the first surface SFA of the substrate 200, but, rather, the shallow trench ST may only partially penetrate, or extend into, the substrate 200.

The substrate 200 may include a deep trench DT, and the photodiode isolation pattern DTI may be within the deep trench DT of the substrate 200.

The deep trench DT may penetrate the substrate 200 from the first surface SFA to the second surface SFB of the substrate 200, for example, with the deep trench DT extending through an entirety of the substrate from the first surface SFA to the second surface SFB.

A depth of the shallow trench ST may be less than a depth of the deep trench DT along the third direction DR3, which is a height direction. For example, the deep trench DT may have a depth (e.g., along the third direction DR3) that is at least double the depth of the shallow trench ST, or at least triple the depth of the shallow trench ST, or at least quadruple the depth of the shallow trench ST. The deep trench DT may have a width (e.g., along the plane direction DRH) that is less than half of the width of the shallow trench ST.

The photodiode isolation pattern DTI may include a first pattern DTI1, a second pattern DTI2, and the shallow trench isolation pattern STI.

The first pattern DTI1 may cover the inner wall of the deep trench DT and, in embodiments, may be in contact with the substrate 200. The second pattern DTI2 may be positioned within, and may at least partially fill, a lower part of the deep trench DT and may be positioned within the first pattern DTI1 such that the first pattern DTI1 lies between the second pattern DTI2 and the substrate 200. The shallow trench isolation pattern STI may fill an upper part of the deep trench DT.

The second pattern DTI2 may be separated from the substrate 200 by the first pattern DTI1.

The first pattern DTI1 may be formed of silicon oxide, silicon nitride, or silicon oxynitride. The first pattern DTI1 may be formed of a metal oxide such as hafnium oxide, aluminum oxide, tantalum oxide, or etc. The second pattern DTI2 may act as a negative fixed charge layer. The second pattern DTI2 may include semiconductor material such as, for example, n-type or p-type doped polysilicon.

Photodiodes PD respectively corresponding to the pixels may be located in the substrate 200.

Light incident from outside may be converted into electrical signals in photodiodes PD. The photodiodes PD may include photodiodes in the substrate 200. The photodiodes PD may be doped with a conductive impurity different from the conductive impurity doped in the substrate 200. For example, the substrate 200 may be doped with P-type impurities, and the photodiodes PD may be doped with N-type impurities.

The N-type impurity region of the photodiode PD may be formed by forming a PN junction with the surrounding P-type impurity region of the substrate 200, and may generate electron-hole pairs by the PN junction when light is incident.

The photodiode isolation pattern DTI may electrically and optically isolate adjacent photodiodes PD.

The shallow trench isolation pattern STI may include silicon oxide, silicon nitride, or a combination thereof.

Alternatively, a shallow trench isolation pattern STI may be a region doped with impurities of the first conductivity type, which is the same as the impurities doped in the substrate 200 at a higher concentration than a doping concentration of the impurities doped in the substrate 200.

Each of the plurality of pixels PX may include active regions AR located adjacent to the first surface SFA of the substrate 200 within the substrate 200. Each active region AR may be separated by the shallow trench isolation pattern STI.

The substrate 200 may include the floating diffusion regions FD1, FD2 adjacent to the first surface SFA.

The floating diffusion regions FD1, FD2 may be doped with a second conductive type impurity different from the first conductive type impurity doped in the substrate 200.

The active regions AR of the plurality of pixels PX may be active regions for the operation of the plurality of transistors.

A plurality of gates GRG1, GRG2, G1, G2, G3, G4, G5, and G6 may be on the active regions AR of the plurality of pixels PX.

Among the plurality of gates RG1, GRG2, G1, G2, G3, G4, G5, and G6, the gates G1 adjacent to the first floating diffusion region FD1 and the second floating diffusion region FD2 may be transfer gates.

Among the plurality of gates RG1, GRG2, G1, G2, G3, G4, G5, and G6, a first gate GRG1 and a second gate GRG2 may form the reset transistor RG and the dual conversion transistor DCG, respectively, together with active regions AR.

Among the plurality of gates RG1, GRG2, G1, G2, G3, G4, G5, and G6, the remaining gates G2, G3, G4, G5, and G6 may be the gates of the source follower transistor SF and the select transistor SEL.

A first structure 300 may be on the first surface SFA of the substrate 200. The first structure 300 may include a plurality of vias ML1, a plurality of wiring layers ML2, ML3, and a plurality of insulating layers IL1, IL2, IL3. The plurality of insulating layers IL1, IL2, IL3 may electrically isolate the plurality of vias ML1 and the plurality of wiring layers ML2, ML3.

The plurality of vias ML1 and the plurality of wiring layers ML2, ML3 may be electrically connected to transistors on the first surface SFA of the substrate 200.

The plurality of vias ML1 and the plurality of wiring layers ML2, ML3 may be formed of tungsten, aluminum, copper, tungsten silicide, titanium silicide, tungsten nitride, titanium nitride, doped polysilicon, or the like.

The plurality of insulating layers IL1, IL2, IL3 may be formed of insulating materials such as silicon oxide, silicon nitride, silicon oxynitride, a low-k material, or the like. The low-k material may include, for example, at least one of Flowable Oxide (FOX), Torene SilaZene (TOSZ), Undoped Silica Glass (USG), Borosilica Glass (BSG), PhosphoSilica Glass (PSG), BoroPhosphoSilica Glass (BPSG), Plasma Enhanced Tetra Ethyl Ortho Silicate (PETEOS), Fluoride Silicate Glass (FSG), Carbon Doped silicon Oxide (CDO), Xerogel, Aerogel, Amorphous Fluorinated Carbon, Organo Silicate Glass (OSG), Parylene, bis-benzocyclobutenes (BCB), SiLK, polyimide, porous polymeric material, or combinations thereof.

The image sensor 1000 may further include a support substrate 400 on the first structure 300, but the support substrate 400 may be omitted. An adhesive member (not shown) may be further located between the support substrate 400 and the first structure 300.

An anti-reflection layer RPL may be on the second surface SFB of the substrate 200. The anti-reflection layer RPL may cover the second surface SFB of the substrate 200 and the photodiode isolation pattern DTI.

The anti-reflection layer RPL may be formed of hafnium oxide (HfO₂), silicon oxide (SiO₂), silicon nitride (SiN), aluminum oxide (Al₂O₃), zirconium oxide (ZrO₂), tantalum oxide (Ta₂O₅), titanium oxide (TiO₂), lanthanum oxide (La₂O₃), praseodymium oxide (Pr₂O₃), cerium oxide (CeO₂), neodymium oxide (Nd₂O₃), promethium oxide (Pm₂O₃), samarium oxide (Sm₂O₃), europium oxide (Eu₂O₃), gadolinium oxide (Gd₂O₃), terbium oxide (Tb₂O₃), dysprosium oxide (Dy₂O₃), holmium oxide (Ho₂O₃), thulium oxide (Tm₂O₃), ytterbium oxide (Yb₂O₃), lutetium oxide (Lu₂O₃), yttrium oxide (Y₂O₃), or a combination thereof.

In one or more embodiments, the anti-reflection layer RPL may include a plurality of layers including different materials and having different thicknesses. In one embodiment, the anti-reflection layer RPL may include a first anti-reflection layer to a third anti-reflection layer sequentially stacked on the second surface SFB of the substrate 200.

The first anti-reflection layer may be a fixed charge layer having a negative fixed charge. Hole accumulation may occur around the fixed charge layer, thereby effectively reducing the occurrence of dark current and white spots.

The third anti-reflection layer may be formed of a metal oxide or a metal fluoride including at least one of hafnium (Hf), zirconium (Zr), aluminum (Al), tantalum (Ta), titanium (Ti), and yttrium (Y). For example, the first anti-reflection layer and the third anti-reflection layer may be hafnium oxide layers, and the second anti-reflection layer may include silicon oxide and/or silicon nitride. However, in other embodiments, the number and relative thickness of the layers constituting the anti-reflection layer RPL may be variously modified.

In another embodiment, the anti-reflection layer RPL may further include a silicon nitride layer disposed between the second anti-reflection layer and the third anti-reflection layer. Each pixel group PGA, PGB may include a color filter CF.

A plurality of color filters CF may be located on an anti-reflection layer RPL and may be separated from each other by a fence pattern IS. The plurality of color filters CF may include, for example, a green filter, a blue filter, and a red filter. The plurality of color filters CF may include, for example, cyan, magenta, or yellow.

The fence patterns IS may surround at least a portion of the color filters CF. In another embodiment, a portion of the color filters CF may not be surrounded by the fence patterns IS, and a portion of the color filters CF may be positioned over the fence patterns IS.

The fence patterns IS may include a low refractive index material. The low refractive index materials may have a refractive index greater than about 1.0 and less than or equal to about 1.4. For example, the low refractive index material may be formed of polymethylmethacrylate (PMMA), silicon acrylate, cellulose acetate butyrate (CAB), silica, or fluoro-silicon acrylate (FSA). For example, the low refractive index material may include a polymer material in which silica (SiOx) particles are dispersed.

When the fence patterns IS are formed of a low-refractive index material having a relatively low refractive index, light incident on the fence patterns IS may be totally reflected and directed toward the center of the photodiode PD of each pixel PX.

The fence patterns IS may prevent light that obliquely enters the color filter CF located at each pixel PX from entering the color filter CF located in an adjacent pixel PX, and accordingly, the fence patterns IS may prevent crosstalk between the plurality of pixels PX.

A micro lens ML may be on the color filters CF and the fence pattern IS.

The micro lenses ML may be transparent. The micro lens ML may be formed of a resin material such as, for example, a styrene-based resin, an acrylic-based resin, a styrene-acrylic copolymer-based resin, or a siloxane-based resin.

The micro lens ML may condense incident light, and the condensed light may be incident on the photodiode PD through the color filter CF.

Each of the pixel groups PGA, PGB may include at least one micro lens ML. According to one or more embodiments, one micro lens ML may be in each of the pixel groups PGA, PGB. According to one or more embodiments, each of the pixel groups PGA, PGB may include a plurality of micro lenses ML corresponding to photodiodes PD within each of the pixel groups PGA, PGB.

A capping layer CPL may be on the micro lens ML to protect the micro lens ML.

As described above, each pixel group region PG may include the first capacitor ACP1 and the second capacitor ACP2 connected between the reset transistor RG and the dual conversion transistor DCG.

The first capacitor ACP1 may overlap the photodiode isolation pattern DTI along the third direction DR3, which extends in a direction perpendicular to the first surface SFA and the second surface SFB of the substrate 200. By overlapping, a vertical axis that extends in the third direction DR3 and is perpendicular to the first surface SFA and the second surface SFB may intersect, or extend through, the first capacitor ACP1, the second pattern DTI2, and the shallow trench isolation pattern STI.

Referring to FIG. 5, the first capacitor ACP1 may include the second pattern DTI2 of the photodiode isolation pattern DTI and a capacitor electrode ACP1P, that overlap with the shallow trench isolation pattern STI interposed between the second pattern DTI2 and the capacitor electrode ACP1P along the third direction DR3. The second pattern DTI2 of the photodiode isolation pattern DTI may serve as another capacitor electrode of the first capacitor ACP1.

The second pattern DTI2 of the photodiode isolation pattern DTI and the capacitor electrode ACP1P may form the first capacitor ACP1 together with the shallow trench separation pattern STI, and the second pattern DTI2 of the photodiode isolation pattern DTI may be a negative (−) terminal, and the capacitor electrode ACP1P may be a positive (+) terminal.

The second pattern DTI2 of the photodiode isolation pattern DTI and the capacitor electrode ACP1P may include a semiconductor material, and more specifically, may include polysilicon doped with n-type or p-type.

The capacitor electrode ACP1P may be formed of the same material, and may be formed at the same time, as gates GRG1, GRG2, G1.

The capacitor electrode ACP1P of the first capacitor ACP1 may be electrically connected to the source-drain regions SD of the reset transistor RG and the dual conversion transistor DCG through contact holes CT1, CT2 of the first structure 300, a connection portion CML1 located on the insulating layer IL1, and a connection pattern CP. For example, the capacitor electrode ACP1P may be located between the contact holes CT1, CT2, and the capacitor electrode ACP1P may be located vertically below (e.g., relative to the third direction DR3) the connection pattern CP and the connection portion CML1. As such, the capacitor electrode ACP1P may be located vertically between (e.g., relative to the third direction DR3) the shallow trench isolation pattern STI and the connection pattern CP.

The first capacitor ACP1 including the second pattern DTI2 and the capacitor electrode ACP1P is formed by forming the capacitor electrode ACP1P on the second pattern DTI2 of the photodiode isolation pattern DTI, so that the first capacitor ACP1 may not additionally occupy a planar area within the pixel, and the first capacitor ACP1 having a desired capacitance may be implemented even in a high-resolution image sensor.

A gate insulating film GIL may be between the active region AR of the substrate 200 and the gates GRG1, GRG2, while a gate oxide film GPL may be on the gates GRG1, GRG2, for example, with the gate oxide film GPL positioned on a top wall of the gates GRG1, GRG2, and a spacer SP may be positioned on the sidewalls of the gates GRG1, GRG2.

Referring to FIG. 6, the second capacitor ACP2 may include a first capacitor electrode ACP2P1 and a second capacitor electrode ACP2P2 that overlap with a dielectric layer ITL therebetween.

The first capacitor electrode ACP2P1 and the second capacitor electrode ACP2P2 may form the second capacitor ACP2 together with the dielectric layer ITL, and the first capacitor electrode ACP2P1 may be a negative (−) terminal, and the second capacitor electrode ACP2P2 may be a positive (+) terminal.

At least a portion of each of the first capacitor electrode ACP2P1, the dielectric layer ITL, and the second capacitor electrode ACP2P2 may be within a trench TRC formed in the substrate 200. The first capacitor electrode ACP2P1 and the second capacitor electrode ACP2P2 may overlap not only along the third direction DR3, which is the height direction, but also along a plane direction DRH that is perpendicular to the third direction DR3. Therefore, the first capacitor electrode ACP2P1 and the second capacitor electrode ACP2P2 may be located within a relatively narrow planar area while increasing the capacitance of the second capacitor ACP2. For example, the first capacitor electrode ACP2P1 may be located below the second capacitor electrode ACP2P2, with the second capacitor electrode ACP2P2 overlapping, and above, the first capacitor electrode ACP2P1. In embodiments, the second capacitor electrode ACP2P2 may not completely overlap the first capacitor electrode ACP2P1, for example, with a first portion of the first capacitor electrode ACP2P1 being overlapped by, and lying below, the second capacitor electrode ACP2P2, while a second portion of the first capacitor electrode ACP2P1 may not be overlapped by the second capacitor electrode ACP2P2. In embodiments, a first portion of the second capacitor electrode ACP2P2 overlaps the first capacitor electrode ACP2P1 while a second portion of the second capacitor electrode ACP2P2 may not overlap the first capacitor electrode ACP2P1. In embodiments, an upper surface of the second capacitor electrode ACP2P2 may be non-planar, with the upper surface of the second capacitor electrode ACP2P2 extending along two separate planes that may be parallel to one another. In embodiments, a lower surface of the second capacitor electrode ACP2P2 may also be non-planar, with the lower surface of the second capacitor electrode ACP2P2 extending along two separate planes that may be parallel to one another. In embodiments, an upper surface of the first capacitor electrode ACP2P1 may be non-planar, with the upper surface of the first capacitor electrode ACP2P1 extending along two separate planes that may be parallel to one another. In embodiments, a lower surface of the first capacitor electrode ACP2P1 may be non-planar, with the lower surface of the first capacitor electrode ACP2P1 extending along two separate planes that may be parallel to one another.

Referring to FIG. 7 together with FIG. 6, the transfer gates G1 of the transfer transistors TG may have a vertical gate shape having an extended portion extending from the first surface SFA of the substrate 200 into the substrate 200, and a depth of the trench TRC formed in the substrate 200 may be substantially the same as a depth of a groove portion GRC where the extended portion of the transfer gates G1 extended into the substrate 200 is located. The depth of the trench TRC and the depth of the groove portion GRC measured from the first surface SFA of the substrate 200 may be greater than the depth of the shallow trench ST.

The trench TRC of the substrate 200 in which at least a portion of each of the first capacitor electrode ACP2P1, the dielectric layer ITL, and the second capacitor electrode ACP2P2 is located, may be formed together with the groove GRC of the substrate 200 in which the extended portion of the transfer gates G1 extending into the substrate 200 is located.

An insulating layer ISL may be located between the trench TRC of the substrate 200 and the first capacitor electrode ACP2P1. The insulating layer ISL may electrically separate the substrate 200 and the second capacitor ACP2.

The dielectric layer ITL of the second capacitor ACP2 may be formed of the same material, and may be formed at the same time, as the gate insulating layer GIL.

The second capacitor electrode ACP2P2 of the second capacitor ACP2 may be formed of the same material, and formed at the same time, as the gates GRG1, GRG2, G1.

The gate oxide film GPL may be on the second capacitor electrode ACP2P2, and the spacer SP may be on the sidewall of the second capacitor electrode ACP2P2, but the spacer SP may be omitted.

A pad GP may be on the first capacitor electrode ACP2P1 of the second capacitor ACP2, and the pad GP may be a ground pad capable of applying a ground potential. The pad GP may be on the portion of the first capacitor electrode ACP2P1 that is not overlapped by the second capacitor electrode ACP2P2.

The first capacitor electrode ACP2P1 and the second capacitor electrode ACP2P2 of the second capacitor ACP2 may include a semiconductor material, and in embodiments, may include polysilicon doped with n-type or p-type.

Although the capacitor electrode ACP1P of the first capacitor ACP1 and the second capacitor electrode ACP2P2 of the second capacitor ACP2 are shown as being directly connected to each other, the embodiment is not limited thereto, and the first capacitor ACP1 and the second capacitor ACP2 may be electrically connected through the first structure 300 without being directly connected.

According to one or more embodiments, the image sensor may include the first capacitor ACP1 and the second capacitor ACP2 connected between the reset transistor RG and the dual conversion transistor DCG, such that the size of charge accumulation may be adjusted. Accordingly, an LCG (Low Conversion Gain) mode can be used when there is a greater amount of light and an HCG (High Conversion Gain) mode can be used when there is a reduced amount light, thus enabling dynamic range extension.

The first capacitor ACP1 includes the second pattern DTI2 of the photodiode isolation pattern DTI and the capacitor electrode ACP1P on the second pattern DTI2, so that the first capacitor ACP1 may not additionally occupy a planar area within the pixel, and the first capacitor ACP1 having a desired capacitance may be implemented even in a high-resolution image sensor. For example, the first capacitor ACP1 may occupy a reduced amount of space due to the capacitor electrode ACP1P and the second pattern DTI2 being arranged in a vertically stacked orientation along the third direction DR3.

At least a portion of each of the first capacitor electrode ACP2P1, the dielectric layer ITL, and the second capacitor electrode ACP2P2 of the second capacitor ACP2 may be within the trench TRC formed in the substrate 200, and the first capacitor electrode ACP2P1 and the second capacitor electrode ACP2P2 may overlap not only along the third direction DR3 that is the height direction, but also along the plane direction DRH that is perpendicular to the third direction DR3. For example, a first axis that extends parallel to the plane direction DRH may intersect both the first capacitor electrode ACP2P1 and the second capacitor electrode ACP2P2, while a second axis that extends parallel to the plane direction DRH and parallel to the first axis may intersect the first capacitor electrode ACP2P1 but not the second capacitor electrode ACP2P2, and a third axis that extends parallel to the first axis may intersect the second capacitor electrode ACP2P2 but not the first capacitor electrode ACP2P1. Therefore, the first capacitor electrode ACP2P1 and the second capacitor electrode ACP2P2 may be located within a relatively narrow planar area while increasing the capacitance of the second ACP2.

The trench TRC of a substrate 200 in which at least a portion of each of the first capacitor electrode ACP2P1, the dielectric layer ITL, and the second capacitor electrode ACP2P2 is located may be formed together with the groove GRC of the substrate 200 in which the extended portion of each transfer gates G1 extending into the substrate 200 is located. The dielectric layer ITL of the second capacitor ACP2 may be formed of the same material, and formed at the same time, and may be part of the same layer as the gate insulating layer GIL, and the capacitor electrode ACP1P and the second capacitor electrode ACP2P2 may be formed of the same material, and formed at the same time, as the gates GRG1, GRG2, G1. Therefore, the first capacitor ACP1 and the second capacitor ACP2 may be formed without complicating the manufacturing process or significantly increasing the manufacturing cost.

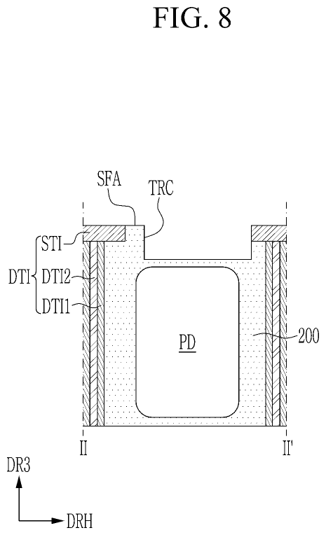

A method of manufacturing an image sensor according to one or more embodiments will be described with reference to FIGS. 8 to 13, along with FIG. 6. FIGS. 8 to 13 are cross-sectional views illustrating a method for manufacturing an image sensor according to one or more embodiments.

Referring to FIG. 8, the trench TRC may be formed in a portion of the substrate 200 from the first surface SFA of the substrate 200. The trench TRC may be deeper than the shallow trench ST. The trench TRC may be formed together with the groove portion GRC of the substrate 200 in which the extended portion of each transfer gates G1 extending into the substrate 200 is located.

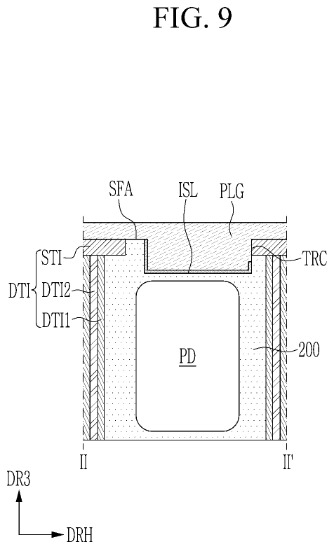

Referring to FIG. 9, the insulating layer ISL may be formed on a lower surface and a side wall of the trench TRC, and then an electrode layer PLG may be formed to fill the trench TRC. A portion of the electrode layer PLG may also be partially located on the first surface SFA of the substrate 200. The electrode layer PLG may include a semiconductor material, more specifically, may comprise polysilicon doped as n-type or p-type.

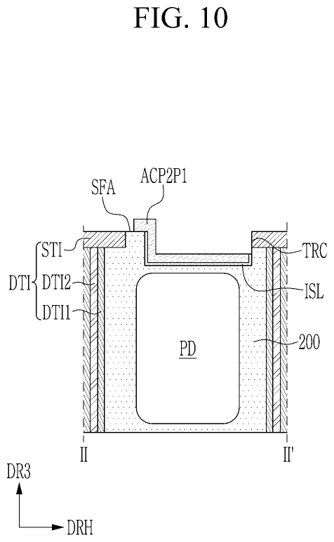

Referring to FIG. 10, the electrode layer PLG may be etched to form the first capacitor electrode ACP2P1 of the second capacitor ACP2. At this time, a portion of the insulating layer ISL may also be removed.

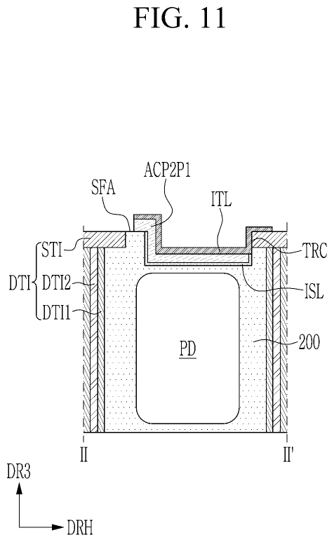

Referring to FIG. 11, a dielectric layer ITL may be formed on the first capacitor electrode ACP2P1. The dielectric layer ITL may be formed together with the gate insulating layer GIL of the transistors.

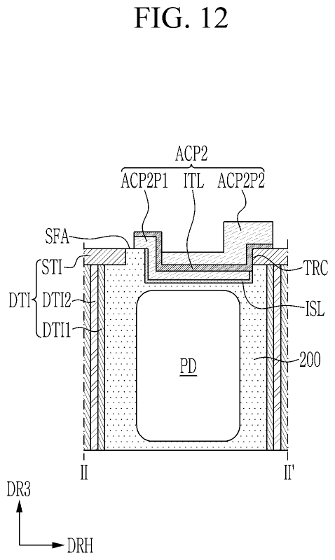

Referring to FIG. 12, the second capacitor electrode ACP2P2 of the second capacitor ACP2 may be formed on the dielectric layer ITL to form the second capacitor ACP2 including the first capacitor electrode ACP2P1, the dielectric layer ITL, and the second capacitor electrode ACP2P2. The second capacitor electrode ACP2P2 may be formed together with the gates GRG1, GRG2, G1. The second capacitor electrode ACP2P2 may include a semiconductor material, and more specifically, may include polysilicon doped with n-type or p-type.

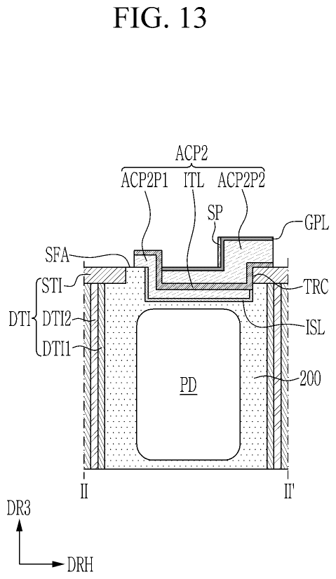

Referring to FIG. 13, the gate oxide film GPL may be formed on the second capacitor electrode ACP2P2, and the spacer SP may be formed on the sidewall of the second capacitor electrode ACP2P2, but the spacer SP may be omitted.

The pad GP may be formed on the first capacitor electrode ACP2P1 to form the second capacitor ACP2 as shown in FIG. 6.

According to the method for manufacturing the image sensor according to one or more embodiments, the first capacitor electrode ACP2P1 may be formed in the trench TRC of the substrate 200, the dielectric layer ITL may be formed together with the same material as the gate insulating layer GIL, and the second capacitor electrode ACP2P2 may be formed together with the same material as gates GRG1, GRG2, G1. As such, only one additional mask may be used to form the second capacitor ACP2 for forming the first capacitor electrode ACP2P1. Accordingly, the second capacitor ACP2 may be formed without significantly increasing the manufacturing cost or complicating the manufacturing process.

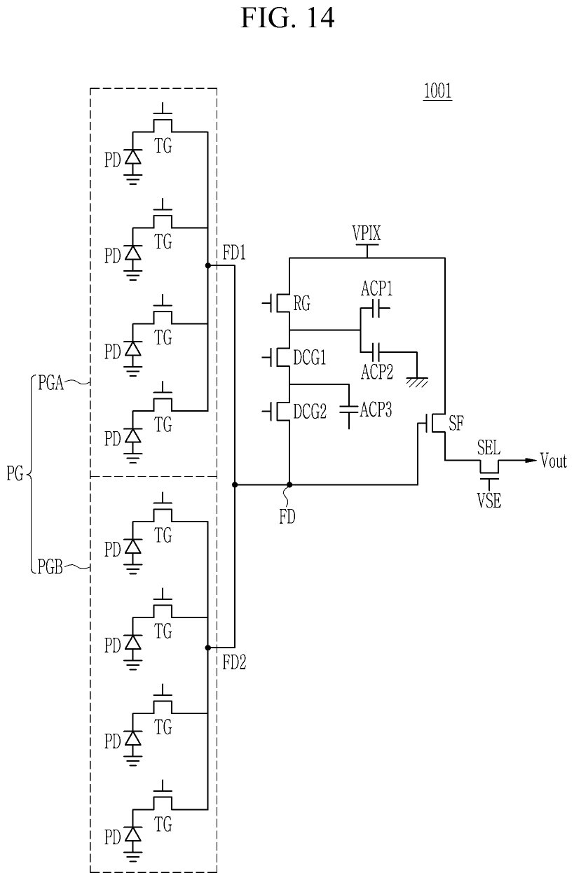

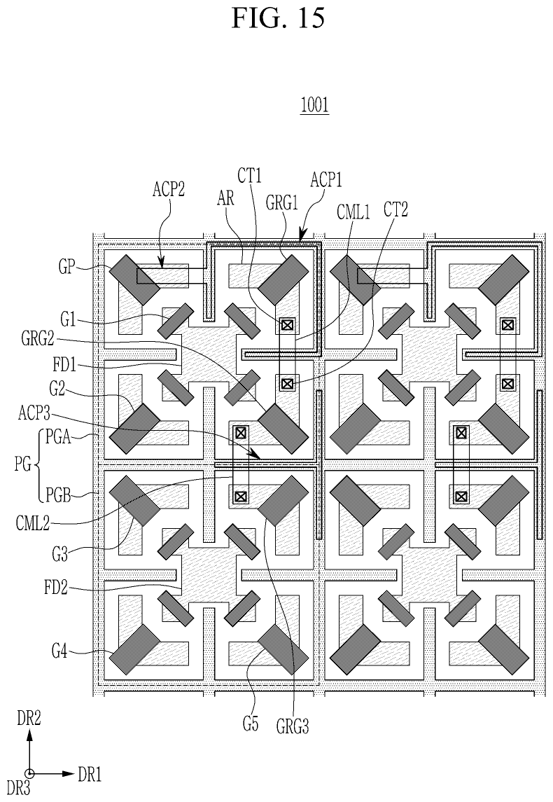

Referring to FIGS. 14 and 15, an image sensor 1001 according to one or more embodiments will be described. FIG. 14 is an equivalent circuit diagram of an image sensor according to one or more embodiments, and FIG. 15 is a plan view of an image sensor according to one or more embodiments.

Referring to FIGS. 14 and 15, the image sensor 1001 according to the present embodiment is similar to the image sensor 1000 according to the previously described embodiment. A detailed description of the same components will be omitted.

Referring to FIG. 14, the image sensor 1001 according to the present embodiment may include a plurality of dual conversion transistors DCG1, DCG2, the first capacitor ACP1 and the second capacitor ACP2 connected between the reset transistor RG and a first dual conversion transistor DCG1, and a third capacitor ACP3 connected between a first dual conversion transistor DCG1 and a second dual conversion transistor DCG2.

Referring to FIG. 15, similar to the first capacitor ACP1 shown in FIG. 5, the third capacitor ACP3 may include the second pattern DTI2 of the photodiode isolation pattern DTI and the capacitor electrode positioned on the photodiode isolation pattern DTI. The third capacitor ACP3 may be electrically connected to the source drain regions SD of the transistors via a connection portion CML2.

According to another embodiment, the third capacitor ACP3 may include the first capacitor electrode ACP2P1 and the second capacitor electrode ACP2P2 that overlap with the dielectric layer ITL therebetween, similar to the second capacitor ACP2 shown in FIG. 6, and at least a portion of each of the first capacitor electrode ACP2P1, the dielectric layer ITL, and the second capacitor electrode ACP2P2 may be within the trench TRC formed in the substrate 200.

Although the first pixel group PGA and the second pixel group PGB sharing the reset transistor RG, the dual conversion transistors DCG1, DCG2, the source follower transistor SF, and the selection transistor SEL are shown as each including four photodiodes PD, the embodiment is not limited thereto, and the number of photodiodes included in the first pixel group PGA and the second pixel group PGB may be variously changed.

Many features of the image sensor according to the previously described embodiment are applicable to the image sensor according to the embodiment shown in FIGS. 14 and 15.

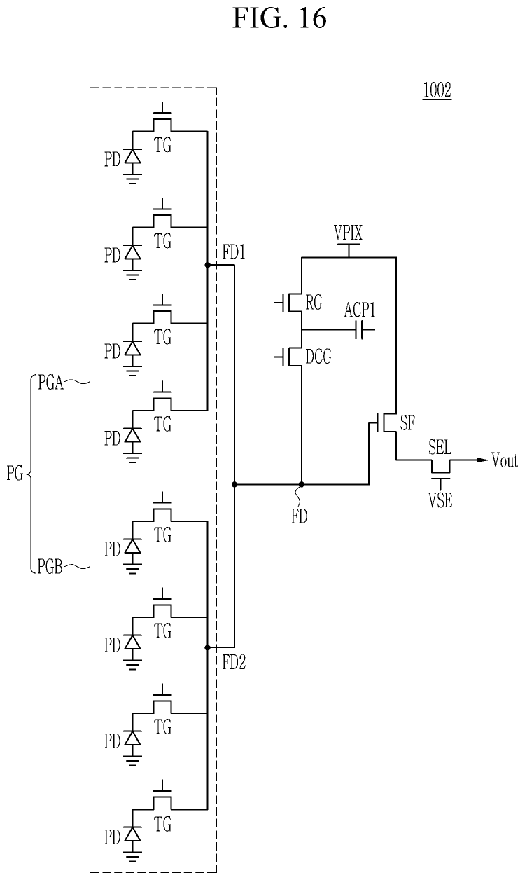

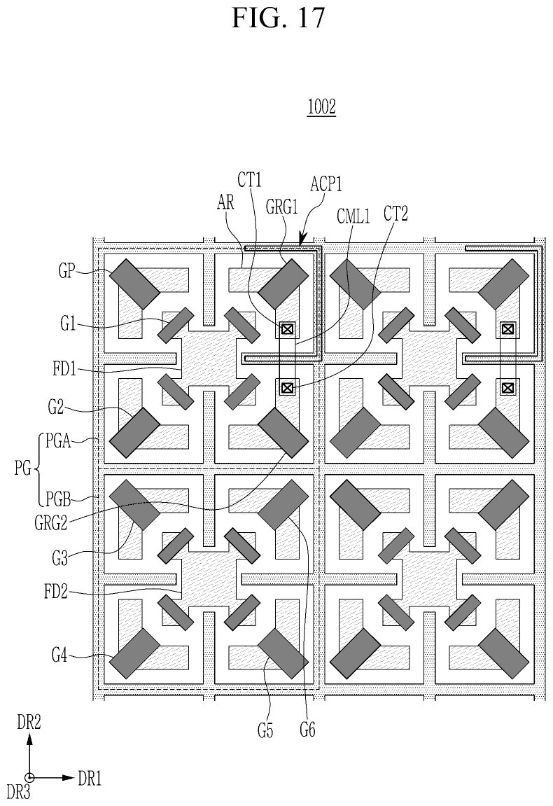

Referring to FIG. 16 and FIG. 17, an image sensor 1002 according to one or more embodiments is described. FIG. 16 is an equivalent circuit diagram of an image sensor according to one or more embodiments, and FIG. 17 is a plan view of an image sensor according to one or more embodiments.

Referring to FIGS. 16 and 17, the image sensor 1002 according to the present embodiment is similar to the image sensors 1000, 1001 according to the previously described embodiments. A detailed description of the same components will be omitted.

Referring to FIG. 16, the image sensor 1002 according to the present embodiment may include the first capacitor ACP1 connected between the reset transistor RG and the dual conversion transistor DCG.

Referring to FIG. 17, the image sensor 1002 according to the present embodiment may include the first capacitor ACP1 shown in FIG. 5.

According to another embodiment, the image sensor 1002 according to the present embodiment may include the second capacitor ACP2 shown in FIG. 6. The image sensor 1002 may include the first capacitor electrode ACP2P1 and the second capacitor electrode ACP2P2 overlapping each other with the dielectric layer ITL therebetween, and at least a portion of each of the first capacitor electrode ACP2P1, the dielectric layer ITL, and the second capacitor electrode ACP2P2 may be within the trench TRC formed in the substrate 200.

Although the first pixel group PGA and the second pixel group PGB, which may share the reset transistor RG, the dual conversion transistor DCG, the source follower transistor SF, and the select transistor SEL, are shown as each including four photodiodes PD, the embodiment is not limited thereto, and the number of photodiodes included in the first pixel group PGA and the second pixel group PGB may be variously changed.

Many of the features of the image sensors according to the embodiments described above are all applicable to the image sensor according to the embodiment shown in FIGS. 16 and 17.

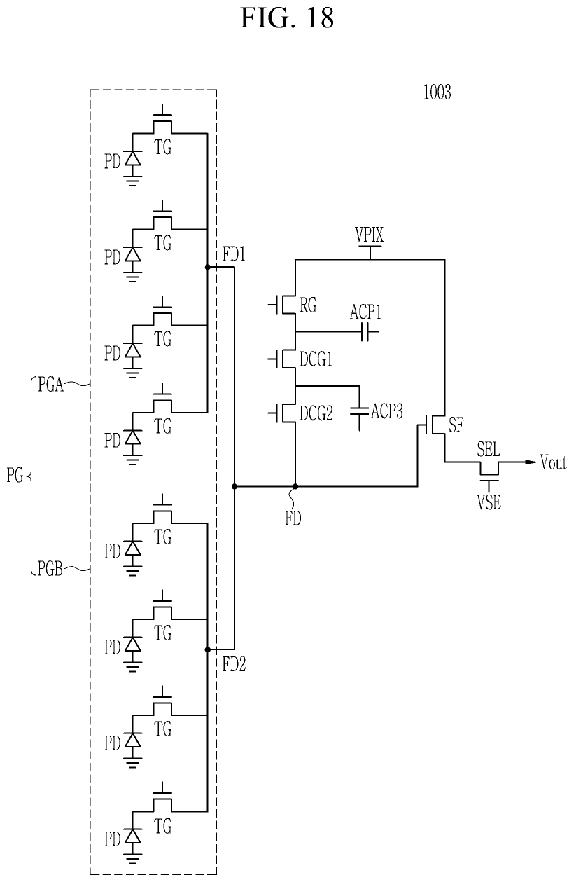

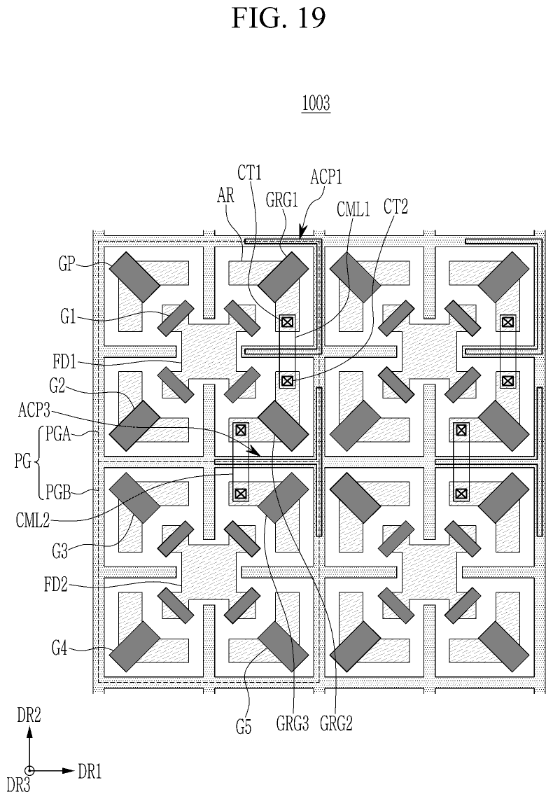

Referring to FIGS. 18 and 19, an image sensor 1003 according to one or more embodiments will be described. FIG. 18 is an equivalent circuit diagram of an image sensor according to one or more embodiments, and FIG. 19 is a plan view of an image sensor according to one or more embodiments.

Referring to FIGS. 18 and 19, the image sensor 1003 according to the present embodiment is similar to the image sensors 1000, 1001, 1002 according to the previously described embodiments. A detailed description of the same components will be omitted.

Referring to FIG. 18, the image sensor 1003 according to the present embodiment may include the first capacitor ACP1 connected between the reset transistor RG and the first dual conversion transistor DCG1, and the third capacitor ACP3 connected between the first dual conversion transistor DCG1 and the second dual conversion transistor DCG2.

Referring to FIG. 19, the image sensor 1003 according to the present embodiment may include the first capacitor ACP1 shown in FIG. 5. In addition, the third capacitor ACP3 may include, similar to the first capacitor ACP1 shown in FIG. 5, the second pattern DTI2 of the photodiode isolation pattern DTI and the capacitor electrode positioned on the photodiode isolation pattern DTI. The third capacitor ACP3 may be electrically connected to the source drain regions SD of the transistors via the connection portion CML2.

According to another embodiment, the first capacitor ACP1 and the third capacitor ACP3 may include the first capacitor electrode ACP2P1 and the second capacitor electrode ACP2P2 that overlap with the dielectric layer ITL therebetween, similar to the second capacitor ACP2 shown in FIG. 6, and at least a portion of each of the first capacitor electrode ACP2P1, the dielectric layer ITL, and the second capacitor electrode ACP2P2 may be within the trench TRC formed in the substrate 200.

The first pixel group PGA and the second pixel group PGB, which may share the reset transistor RG, the dual conversion transistors DCG1, DCG2, the source follower transistor SF, and the selection transistor SEL, are shown as each including four photodiodes PD, but the embodiment is not limited thereto, and the number of photodiodes included in the first pixel group PGA and the second pixel group PGB may be variously changed.

Many of the features of the image sensors according to the embodiments described above are all applicable to the image sensor according to the embodiment shown in FIGS. 17 and 18.

While an example embodiment has been described above, the embodiments are not limited thereto, and it is possible to implement various modifications within the scope of the claims, the detailed description of this disclosure, and the accompanying drawings, and it is natural that these also fall within the scope of this disclosure.

What is claimed is:

1. An image sensor, comprising:
a floating diffusion region in a substrate;
a first transistor connected to the floating diffusion region and a second transistor connected to the first transistor; and
a capacitor connected between the first transistor and the second transistor,
wherein the capacitor includes a first electrode and a second electrode that overlap with an insulating layer interposed therebetween,
wherein the substrate has a trench, and
wherein at least a portion of the first electrode is located in the trench and at least a first portion of the second electrode is located on the substrate.

2. The image sensor of claim 1, further comprising:
a plurality of photodiodes in the substrate; and
a photodiode isolation pattern between adjacent photodiodes of the plurality of photodiodes, and
wherein the second electrode of the capacitor is on the photodiode isolation pattern.

3. The image sensor of claim 2,
wherein the photodiode isolation pattern includes a first pattern in a deep trench of the substrate, a second pattern positioned within a lower portion of the deep trench, and a shallow trench isolation pattern filling an upper portion of the deep trench, and
wherein the first electrode of the capacitor is the second pattern.

4. The image sensor of claim 3,
wherein the insulating layer of the capacitor is the shallow trench isolation pattern of the photodiode isolation pattern.

5. The image sensor of claim 1,
wherein a second portion of the second electrode is in the trench.

6. The image sensor of claim 5,
wherein the second electrode is formed of the same material as a gate of the first transistor.

7. The image sensor of claim 6,
wherein the insulating layer is formed of the same material as a gate insulating layer of the first transistor.

8. The image sensor of claim 5,
wherein the first electrode and the second electrode overlap along a height direction perpendicular to a first surface of the substrate and along a planar direction parallel to the first surface.

9. The image sensor of claim 5, further comprising
a pad located on the first electrode.

10. The image sensor of claim 9,
wherein the pad is a ground pad.

11. An image sensor, comprising:
a floating diffusion region in a substrate;
a first transistor connected to the floating diffusion region and a second transistor connected to the first transistor; and
a first capacitor and a second capacitor connected in parallel between the first transistor and the second transistor.

12. The image sensor of claim 11, further comprising:
a plurality of photodiodes in the substrate; and
a photodiode isolation pattern between adjacent photodiodes of the plurality of photodiodes, and
wherein a second electrode of the first capacitor is on the photodiode isolation pattern.

13. The image sensor of claim 12,
wherein the photodiode isolation pattern includes a first pattern located in a deep trench of the substrate, a second pattern positioned within a lower portion of the deep trench, and a shallow trench isolation pattern filling an upper portion of the deep trench, and
wherein a first electrode of the first capacitor is the second pattern.

14. The image sensor of claim 13,
wherein an insulating layer of the first capacitor is the shallow trench isolation pattern of the photodiode isolation pattern.

15. The image sensor of claim 11,
wherein the substrate has a trench, and
wherein at least a portion of a first electrode of the second capacitor and at least a portion of a second electrode of the second capacitor are in the trench.

16. The image sensor of claim 15,
wherein the second electrode of the second capacitor is formed of the same material as a gate of the first transistor.

17. The image sensor of claim 16,
wherein an insulating layer of the second capacitor is formed of the same material as a gate insulating layer of the first transistor.

18. The image sensor of claim 15,
wherein the first electrode and the second electrode of the second capacitor overlap along a height direction perpendicular to a first surface of the substrate and along a planar direction parallel to the first surface.

19. The image sensor of claim 15, further comprising
a pad on the first electrode of the second capacitor.

20. The image sensor of claim 19,
wherein the pad is a ground pad.
